(19) United States
(12) Patent Application Publication
(10) Pub. No.: US 2014/0190736 A1
(43) Pub. Date: Jul. 10, 2014

(54) RADIATION-CURABLE RUBBER ADHESIVE/SEALANT

(71) Applicants: Jie Cao, Hillsborough, NJ (US); Donald E. Herr, Doylestown, PA (US)

(72) Inventors: Jie Cao, Hillsborough, NJ (US); Donald E. Herr, Doylestown, PA (US)

(21) Appl. No.: 13/565,952

(22) Filed: Aug. 3, 2012

Related U.S. Application Data
(63) Continuation of application No. 12/293,719, filed on Jan. 12, 2010, now abandoned.

(51) Int. Cl. H01L 23/29

(52) U.S. Cl. CPC H01L 23/293
USPC 174/521; 522/182; 522/186

(57) ABSTRACT

A radiation-curable adhesive/sealant composition comprises a radiation-curable rubber resin, one or more photoinitiators or photosensitizers, and optionally, one or more inorganic or organic fillers.

### CROSS-REFERENCE TO RELATED APPLICATIONS

This application is a continuation of U.S. patent application Ser. No. 12/293,719 filed Jan. 12, 2010, which is a 371 of International Patent Application No. PCT/US2006/11442 filed Mar. 29, 2006, the contents of both of which are incorporated herein by reference.

This Invention was made with support from the Government of the United States of America under Agreement No. MDA972-93-2-0014 awarded by the Army Research Laboratories. The Government has certain rights in the Invention.

### FIELD OF THE INVENTION

This invention relates to radiation-curable adhesives or sealants. In a preferred embodiment, it relates to adhesives and sealants for electronic and optoelectronic devices, such as organic light emitting diodes.

### BACKGROUND OF THE INVENTION

It is well known that a variety of packaged electronic devices require moisture protection to achieve a specified operating or storage lifetime. In particular, the relative humidity within the encapsulated packages of highly moisture-sensitive electronic/optoelectronic devices, such as organic light-emitting devices (OLED), polymer light-emitting devices, charge-coupled device (CCD) sensors, micro-electro-mechanical sensors (MEMS), liquid crystal devices (LCD), and electrophoretic devices, must be controlled below a certain level, particularly below 1000 ppm or even in some cases below 100 ppm, in order to fully protect the organic light-emitting layers, electrodes, or other moisture-sensitive components.

There are several approaches used in the prior art to protect encapsulated or packaged devices from water. These techniques do not always work: organic sealants may not meet the stringent moisture permeation requirement; moisture impermeable solder sealants may have melting temperatures that are too high for temperature sensitive devices; and desiccant packages attached on the device inner wall may block light emission out of the device, a particular problem for top-emitting organic light-emitting diodes.

### BRIEF DESCRIPTION OF THE DRAWINGS

FIG. 1 is a perimeter sealed calcium button device.

FIG. 2 is a calcium button device using a laminating adhesive.

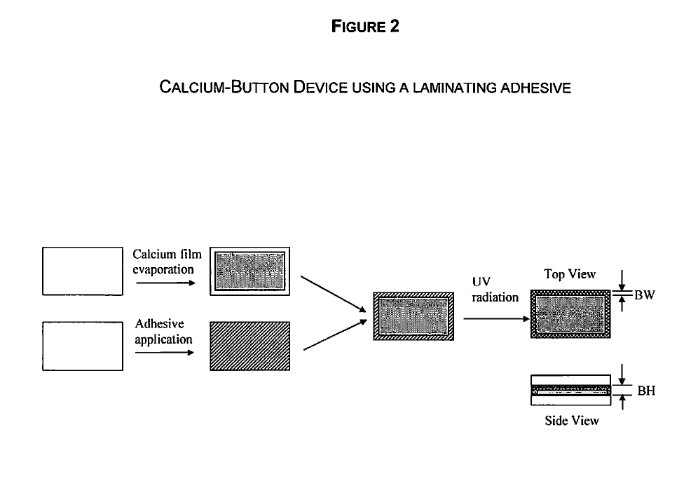

### SUMMARY OF THE INVENTION

This invention is a radiation-curable composition comprising a radiation-curable barrier rubber resin not containing siloxane functionality, a radiation-curable reactive diluent, and a photoinitiating system comprising one or more photoinitiators and optionally one or more photosensitizers. These materials has the properties of both a sealant and an adhesive, hereinafter, sealant/adhesive, and are suitable for sealing highly moisture-sensitive electronic, optoelectronic, or similar devices. The materials are capable of bonding two substrates together to form a sealed enclosure after radiation curing of the adhesive. In another embodiment this invention is an electronic or optoelectronic device, disposed on a substrate and encapsulated with a lid in which the lid and substrate are bonded together with the sealant/adhesive along the perimeter of the substrate and lid or disposed on the whole area between the substrate and the lid.

### DETAILED DESCRIPTION OF THE INVENTION

All references cited herein are incorporated in their entirety by reference. In this specification the term radiation curing refers to the cure of a resin or resin/filler system through exposure to actinic radiation. Actinic radiation is electromagnetic radiation that induces a chemical change in a material, and for purposes within this specification and claims will include electron-beam curing. In most cases, such radiation is ultraviolet (UV) or visible light. The initiation of this cure is achieved through the use of an appropriate photoinitiator.

Suitable resins are polyisobutylenes or butyl rubbers containing functional groups that are radiation curable (hereinafter, barrier rubber resins, rubber resins, or sealant/adhesives). Exemplary materials are olefin-terminal polyisobutylene, polyisobutylene acrylates, polyisobutylene epoxies, polyisobutylene vinyl ethers, butyl rubber, and butyl rubber derivatives (such as, epoxidized butyl rubber, acrylated butyl rubber, maleated butyl rubber, mercaptan functional butyl rubber, and like compounds). Representative polyisobutylene acrylates are described in U.S. Pat. No. 5,171,760 issued to Edison Polymer Innovation Corp., U.S. Pat. No. 5,665,823 issued to Dow Corning Corp., and Polymer Bulletin, Vol. 6, pp. 135-141 (1981), T. P. Liao and J. P. Kennedy. Representative polyisobutylene epoxy materials are described in Polymer Material Science and Engineering, Vol. 58, pp. 869 (1988) and in the Journal of Polymer Science, Part A, Polymer Chemistry, Vol. 28 pp. 89 (1990), J. P. Kennedy and B. Ivan. Representative polyisobutylene vinyl ethers are described in Polymer Bulletin, Vol. 25, pp. 633 (1991), J. P. Kennedy and coworkers, and in U.S. Pat. No. 6,054,549, 6,706,779B2 issued to Dow Corning Corp. Representative radiation curable butyl rubbers are described in RadTech North America proceedings, pp. 77, (1992), N. A. Merrill, I. J. Gardner and V. L. Hughes.

These rubber resins contain reactive functionalities that are curable by radiation. Such reactive functionalities include, but are not limited to, those selected from the group consisting of glycidyl epoxy, aliphatic epoxy, cycloaliphatic epoxy; oxetane; acrylate, methacrylate, itaconate; maleimide; vinyl, propenyl, crotyl, allyl, and propargyl ether and thio-ethers of those groups; maleate, fumarate, and cinnamate esters; styrenic; acrylamide and methacrylamide; chalcone; thiol; allyl, alkenyl, and cycloalkenyl groups.

The radiation-curable reactive diluent will be any of the radiation-curable resins known to those with experience in the field of UV curable materials and filled polymer composites. The resins may be small molecules, oligomers, or polymers, and will be chosen by the practitioner as appropriate for the end use application. If fillers are used, the particular filler chosen may also be varied depending on the rheological requirements needed for a particular optoelectronic or electronic device. The cure mechanism also may vary (cationic, radical, etc.), to suit the particular resin and filler system chosen.

The backbone of the radiation-curable resins is not limited. The reactive functionalities on the resins will be those reactive to the initiators or catalysts formed by exposure to radiation and include, but are not limited to, epoxies, selected from glycidyl epoxy, aliphatic epoxy, and cycloaliphatic epoxy; oxetane; acrylate and methacrylate; itaconate; maleimide; vinyl, propenyl, crotyl, allyl, and propargyl ether and thio-ethers of those groups; maleate, fumarate, and cinnamate esters; styrenic; acrylamide and methacrylamide; chalcone; thiol; allyl, alkenyl, and cycloalkenyl groups.

Suitable cationic polymerizable radiation-curable resins include epoxies, oxetanes, vinyl ethers, and propenyl ethers. Representative epoxy resins are glycidyl ethers and cycloaliphatic epoxies, which are commercially available from a number of sources known to those skilled in the art.

Representative aromatic liquid glycidyl ethers include bisphenol F diglycidyl ether (sold under the trade name Epikote 862 from Resolution Performance Products) or bisphenol A diglycidyl ether (sold under the trade name Epikote 828 from Resolution Performance Products). Representative solid glycidyl ethers include tetramethylbiphenyldiglycidyl ether (sold under the trade name RSS 1407) and resorcinol diglycidyl ether (sold under the trade name Erisys RDGE® available from CVC Specialty Chemicals, Inc.). Other aromatic glycidyl ethers are commercially available under the trade names Epon 1031, Epon 164, and SU-8 available from Resolution Performance Products.

Representative non-aromatic glycidyl epoxy resins include an hydrogenated bisphenol A diglycidylether (sold under the trade name EXA-7015 from Dainippon Ink & Chemicals) or cyclohexanedimethylol diglycidyl ether available from Aldrich Chemical Co.

Representative cycloaliphatic epoxy resins include ERL 4221 and ERL 6128 available from Dow Chemical Co. A representative oxetane resin is OXT-121 available from Toagosei. Representative vinyl ether molecules include cyclohexanedimethylol divinyl ether (Rapicure-CHVE), tripropylene glycol divinyl ether (Rapicure-DPE-3) or dodecyl vinyl ether (Rapicure-DDVE) all available from International Specialty Products. Analogous vinyl ethers are also available from BASF.

Suitable radically polymerizable radiation-curable resins include acrylates, maleimides, or thiol-ene based resins. In many cases, combinations of these three resins can be utilized to tailor the properties of the sealant/adhesive material.

Representative acrylate resins include hexane diol diacrylate, trimethylolpropane triacrylate, cyclohexanedimethylol diacrylate, dicyclo-pentadienedimethylol diacrylate, tris(2-hydroxyethyl)isocyanurate triacrylate, poly(butadiene)dimethacrylate, and bisphenol A based acrylated epoxy. Such resins are commercially available from Sartomer and UCB Chemicals.

Representative liquid maleimide resins are described, for example, in U.S. Pat. Nos. 6,265,530, 6,034,194, and 6,034,195, which are incorporated herein in their entirety by this reference. Particularly suitable maleimide resins have the structures

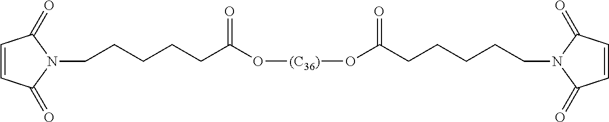

in which (C₃₆) represents a hydrocarbon moiety having 36 carbons, which can be a straight or branched chain, with or without cyclic structures;

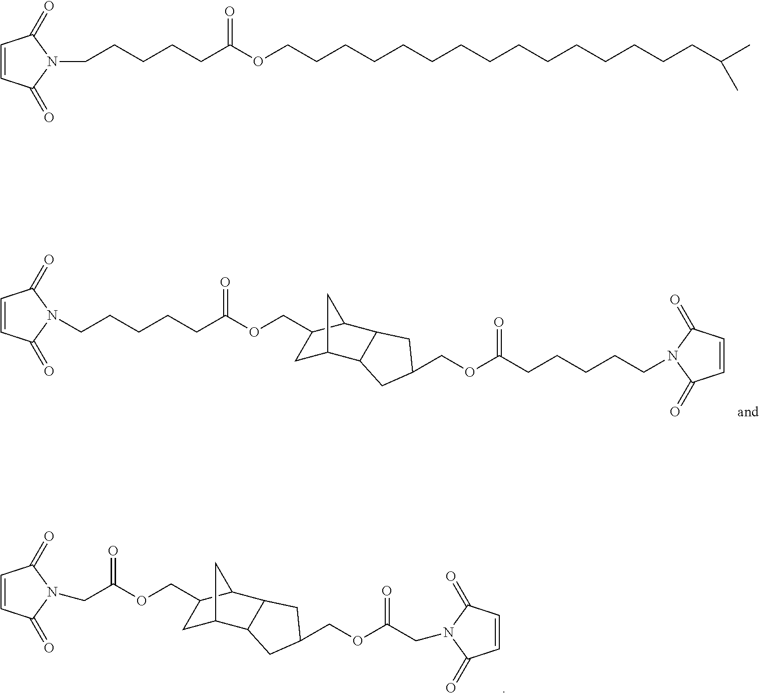 [SMILES: CC(C)CCCCCCCCCCCCCCCOC(=O)CCCCCN1C(=O)C=CC1=O ; O=C(CCCCCN1C(=O)C=CC1=O)OCC1CC2C3CC(COC(=O)CCCCCN4C(=O)C=CC4=O)C(C3)C2C1 ; O=C(CN1C(=O)C=CC1=O)OCC1CC2C3CC(COC(=O)CN4C(=O)C=CC4=O)C(C3)C2C1]

Representative thiol-ene radically photopolymerizable systems include the pentaerythritoltetrakis(3-mercaptopropionate)/triallyl-isocyanurate system. Other useful thiols include those described in U.S. Pat. No. 5,919,602 issued to MacDermid Acumen, Inc. Other useful polyenes include diallylchlorendate (sold under the trade name BX-DAC) and tetraallylbisphenol A, both available from Bimax, Inc.

Additional suitable radiation-curable resins, and photoinitiators for those resins, will include those found in literature sources such as Fouassier, J-P., Photoinitiation, Photopolymerization and Photocuring Fundamentals and Applications 1995, Hanser/Gardner Publications, Inc., New York, N.Y.

The selection of a photoinitiating system for the inventive radiation curable barrier materials is familiar to those skilled in the art of radiation curing. The photoinitiating system will comprise one or more photoinitiators and optionally one or more photosensitizers. The selection of an appropriate photoinitiator is highly dependent on the specific application in which the barrier sealant is to be used. A suitable photoinitiator is one that exhibits a light absorption spectrum that is distinct from that of the resins, fillers, and other additives in the radiation curable system.

If the sealant must be cured through a cover or substrate, the photoinitiator will be one capable of absorbing radiation at wavelengths for which the cover or substrate is transparent. For example, if a barrier sealant is to be cured through a sodalime glass coverplate, the photoinitiator must have significant UV absorbance above ca. 320 nm. UV radiation below 320 nm will be absorbed by the sodalime glass coverplate and not reach the photoinitiator. In this example, it would be beneficial to include a photosensitizer with the photoinitiator into the photoinitiating system, to augment the transfer of energy to the photoinitiator.

For cationically photopolymerizable systems, the most useful photoinitiators are diaryliodonium salts and triarylsulfonium salts containing anions such as, but not limited to fluorinated anions, such as BF₄⁻, PF₆⁻, AsF₆⁻ or SbF₆⁻. Commercially available representative iodonium salts include PC2506 (Polyset), UV9380C (GE silicones), and Rhodorsil 2074 (Rhodia). Other suitable cationic photoinitiators are sulfonium salts, a representative sulfonium salt being UVI-6974 (Dow Chemical). Depending on the application, photosensitizers such as isopropylthioxanthone (ITX) and chloropropoxythioxanthone (CPTX), both available from Aldrich and other vendors, are useful in combination with iodonium salt photoinitiators. Radical photoinitiators are available from Ciba Specialty Chemicals and other vendors. Representative useful radical photointiators from Ciba include Irgacure 651, Irgacure 819, and Irgacure 907. Other photoinitiators are disclosed in Ionic Polymerizations and Related processes, 45-60, 1999, Kluwer Academic Publishers; Netherlands; J. E. Puskas et al. (eds.). Photoinitiators will be used in amounts ranging from 0.1 wt % to 10 wt %.

Inorganic fillers may be used to improve the material properties or the rheology of the compositions. There are many such fillers that are useful in the inventive UV curable sealants/adhesives. Representative fillers include, but are not limited to, ground quartz, fused silica, amorphous silica, talc, glass beads, graphite, carbon black, alumina, clays, mica, aluminum nitride, and boron nitride. Metal powders and flakes consisting of silver, copper, gold, tin, tin/lead alloys, and other alloys also are suitable fillers for conductive applications. Organic filler powders such as poly-(tetrachloro-ethylene), poly(chlorotrifluoroethylene), poly(vinylidene chloride) may also be used. The type and amount of such fillers suitable for use in radiation-curable compositions is within the expertise of the practitioner skilled in the art. Generally, however, such fillers will be present in amounts ranging from 1 wt % to 90 wt %. of the total formulation.

In a further embodiment, this invention is an electronic or optoelectronic device, disposed on a substrate and encapsulated with a lid in which the lid and substrate are bonded together with the sealant/adhesive as described above in this specification. In one embodiment, the desiccant-filled sealant/adhesive is disposed along the perimeter junction of the substrate and lid. In another embodiment, the desiccant-filled sealant/adhesive is disposed over those areas of the substrate and lid that need to be protected.

### EXAMPLES

The moisture barrier performance of sealants can be evaluated by a test known as the Ca-button test, in which the time is measured for which it takes a thin film of calcium metal encapsulated into a device to decay to a calcium salt through reaction with water. The longer the lifetime of the calcium metal film before decay, the lower the moisture permeation into the device and the better the sealant/adhesive protecting the device.

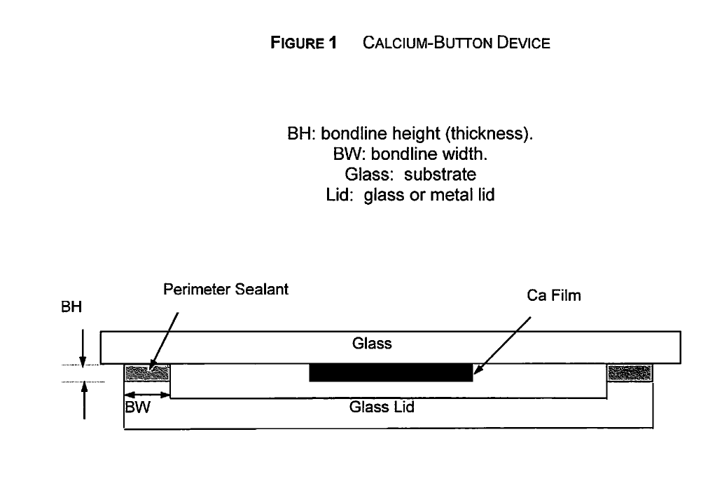

A Ca-button device as used in these examples is shown in FIG. 1, in which BH is the bondline height (thickness) of the perimeter sealant/adhesive; BW is the bondline width of the perimeter sealant/adhesive; glass is the substrate on which the calcium metal film is disposed; and lid is the glass or metal lid used to encapsulate the resultant device.

The device was assembled in a N₂-filled glove box. A thin Ca film was first evaporated on a glass substrate (26 mm×15.5 mm×1.1 mm) (L×W×H) by vapor deposition to a thickness of 100 nm and a geometry of 23 mm×12.5 mm (L×W). The BW of sealant/adhesive is 1.5 mm. The Ca film was encapsulated by a lid using a sealant/adhesive that was dispensed on whole area of the lid. The sealant joint was cured by a UV-radiation spot cure unit to bind the substrate and the lid together with a dose of 3.0 J/cm² of UV-A radiation.

The sealed Ca-button device was placed in an environment controlled to 65° C./80% RH (relative humidity). Initially, the calcium metal film is a metallic mirror capable of reflecting light. Upon exposure to moisture the metallic film turns to a calcium salt, becomes transparent, and no longer reflects. The calcium film in the button device was continuously monitored by a proprietary reflectance unit in order to identify the time when the calcium metal film was fully decayed. Since moisture can only permeate into the enclosed device through the exposed sealant layer, the lifetime of a Ca-button can be used to evaluate moisture barrier performance.

The sealed Ca-button device was placed in an environment controlled to 65° C./80% RH (relative humidity). Initially, the calcium metal film is a metallic film. Upon exposure to moisture permeated through the edge of seal, the metallic film turns to a calcium salt, becomes transparent. Thus, the area of the metallic film becomes smaller vs. time. The area of the calcium film in the button device was periodically monitored and measured in order to identify the time when the area of the calcium metal film reached to 70% of its original area, which is defined as Ca-button lifetime. Since moisture can only permeate into the enclosed device through the exposed sealant layer, the lifetime of a Ca-button can be used to evaluate moisture barrier performance.

Example sealant/adhesive compositions were prepared for water permeability testing using the Ca-button test by mixing the composition components in a FlackTek Speedmixer™ and degassed before application to the Ca-button device. The compositions were applied to the Ca-button device in a N₂ filled glove box to avoid moisture absorption by the Ca-button and desiccants.

EXAMPLE. Formulations were prepared as recited above to contain a radiation-curable rubber resin. As shown in Table 1, formulation 1(a) contained a polyisobutylene diacrylate resin (Mₙ=5300, 70 part by weight), which was prepared from the method developed in Kennedy's group (T. P. Liao and J. P. Kennedy, Polymer Bulletin, Vol. 6, pp. 135-141 (1981)), a diacrylate resin (Sartomer SR833S, 30 part by weight), and a radical photoinitiator (Irgacure 651, 0.3 part by weight). The water permeability is 4.5 g·mil/100 in²·day measured by Mocon Permeatran 3/33 at 50° C./100% RH. Formulation 1(b) contained a liquid rubber resin, mostly a styrene-butadiene-styrene copolymer with acrylic side-chain addition. The permeability for formulation 1(b) is 18 g˜mil/100 in²·day. As shown in Table 1, formulation 1(a) showed better Ca-button lifetime than formulation 1(b), implying that the better resin moisture barrier performance of the resin containing the polyisobutylene diacrylate resin improves device lifetime.

TABLE 1
Sealant1(a) (barrier rubber), 1(b) (non-barrier rubber):

| | Parts by | |
|---|---|---|
| | Weight | |
| Component | 1-a | 1-b |
| Polyisobutylene diacrylate | 70 | 0 |
| (Mₙ = 5300) | | |
| Sartomer SR833S | 30 | 0 |
| Acrylated polyisoprene | 0 | 99.5 |
| Irgarcure 651 | 0.3 | 0.5 |
| Permeability (g · mi1/100 in² · day) | 4.5 | 18 |
| at 50° C./100% RH | | |
| Bondline thickness (mil) | 1.3 | 1.3 |
| Ca-button lifetime (hrs) | 88 | 4.5 |

1. A radiation-curable adhesive/sealant composition comprising:
a) a radiation-curable polyisobutylene or butyl rubber barrier rubber resin containing reactive functionality selected from the group consisting of glycidyl epoxy, aliphatic epoxy, cycloaliphatic epoxy, oxetane, acrylate and methacrylate, and no siloxane functionality,
b) a radiation-curable resin diluent
c) a photoinitiating system comprising one or more photoinitiators and optionally one or more photosensitizers,

2. (canceled)

3. (canceled)

4. The radiation-curable adhesive/sealant in accordance with claim 1 in which the radiation-curable diluent contains reactive functionality selected from the group consisting of glycidyl epoxy, aliphatic epoxy, cycloaliphatic epoxy and oxetane.

5. The radiation-curable adhesive/sealant in accordance with claim 1 in which the radiation-curable diluent contains reactive functionality selected from the group consisting of acrylate and methacrylate.

6. A device, disposed on a substrate and encapsulated with a lid in which the lid and substrate are bonded together with a sealant/adhesive disposed on the whole area between the substrate and the lid, the sealant/adhesive comprising the composition according to claim 1.

7. A device, disposed on a substrate and encapsulated with a lid in which the lid and substrate are bonded together with a sealant/adhesive disposed along the perimeter of the substrate and the lid, the sealant/adhesive comprising the composition according to claim 1.
